(19) United States
(12) Patent Application Publication
(10) Pub. No.: US 2011/0277838 A1
(43) Pub. Date: Nov. 17, 2011

(54) Photovoltaic Devices Employing Ternary Compound Nanoparticles

(75) Inventors: Wanli Ma, El Cerrito, CA (US); A. Paul Alivisatos, Berkeley, CA (US)

(73) Assignee: THE REGENTS OF THE UNIVERSITY OF CALIFORNIA, Oakland, CA (US)

(21) Appl. No.: 13/046,672

(22) Filed: Mar. 11, 2011

Related U.S. Application Data
(60) Provisional application No. 61/313,669, filed on Mar. 12, 2010.

(51) Int. Cl. H01L 31/0368; C01B 19/00; B82Y 40/00; B82Y 99/00

(52) U.S. Cl. 136/258; 423/508; 977/896; 977/948

(57) ABSTRACT

The present invention provides a photovoltaic device. In an exemplary embodiment, the photovoltaic device includes a substrate having a thin film disposed thereon, where the thin film includes alloyed ternary nanocrystals. The present invention provides also provides a method of making ternary compound nanocrystals. In an exemplary embodiment, the method includes (1) degassing a solution of PbO, oleic acid and 1-octadecene (ODE) in a container, (2) heating the solution in the container, (3) injecting a first mixture of trioctylphosphine (TOP):Se solution, TMS2S, diphenylphosphine (DPP) and ODE into the heated solution, thereby forming a second mixture in the container, (4) adding ODE to the second mixture in the container, (5) growing the nanocrystals in the second mixture in a reaction in the container, and (6)_quenching the reaction, thereby resulting in precipitated nanocrystals in the container. In a further embodiment, the present invention further includes purifying the precipitated nanocrystals.

### RELATED APPLICATIONS

The application claims priority to U.S. Provisional Patent Application Ser. No. 61/313,669, filed Mar. 12, 2010, which is herein incorporated by reference in its entirety.

### STATEMENT OF GOVERNMENTAL SUPPORT

This invention was made with government support under Contract No. DE-AC02-05CH11231 awarded by the U.S. Department of Energy. The government has certain rights in the invention.

### FIELD OF THE INVENTION

The present invention relates to the field of nanoparticles, and particularly relates to photovoltaic devices employing ternary compound nanoparticles.

### BACKGROUND OF THE INVENTION

Colloidal semiconductor nanocrystals display a wealth of size-dependent physical and chemical properties, including quantum confinement effects, shape dependent electronic structure,^{1, 2} and control over assembly through modification of surface functionalization.^{3, 4} Photovoltaic devices are an easily recognized potential application for nanocrystals due, in part, to their high photoactivity, solution processability and low cost of production. Several schemes for using nanocrystals in solar cells are under active consideration, including nanocrystal-polymer composites,⁵ nanoparticle array solar cells,⁶ films of partially sintered nanoparticles,⁷ and nanocrystal analogues to dye-sensitized solar cells.⁸

A persistent challenge for any nanoparticle-based solar cell is to take advantage of quantum confinement effects to improve the optical absorption process without overly hindering the subsequent transport of charge to the electrodes. Various binary semiconductor nanoparticles, like CdSe, CdTe, Cu₂S, InP, and InAs, have been explored for photovoltaic devices but the reported efficiencies remain low, mostly limited by poor charge transport between the nanocrystals.^{5, 7-12} With so many parameters to adjust in terms of size and shape, little work has focused on ternary or quaternary compositions of nanoparticles for solar cells. Yet it is well known from thin film solar cell studies that such compositional tuning can sometimes yield significant improvements in performance.

The Pb chalcogenide family of nanocrystals has been actively investigated for nanocrystal solar cell applications because they have such large exciton Bohr radii (PbS 18 nm, PbSe 47 nm, and PbTe 150 nm). In the limit where the nanocrystals are only a tenth or so of the bulk exciton diameter, electrons and holes can tunnel through a thin organic surface coating, and therefore strong electronic coupling between particles facilitates transport of charge between nanocrystals. So far, solar cells based on binary compositions of PbSe and PbS nanocrystals have been investigated.

PbSe nanocrystal solar cells generate larger short circuit photocurrents while PbS nanocrystal devices with similar bandgap have shown a larger V_{OC}.⁶

Moreover, the properties of PbS and PbSe lead to an ideal substitutional alloy: the atomic anion radii are within 15% of each other, the lattice mismatch factor is only 2% between PbS and PbSe (see Supporting Information for the similarity of the XRD patterns), and, of course, the anions are isovalent.

### SUMMARY OF THE INVENTION

The present invention provides a photovoltaic device. In an exemplary embodiment, the photovoltaic device includes a substrate having a thin film disposed thereon, where the thin film includes alloyed ternary nanocrystals. In an exemplary embodiment, the thin film includes a photoactive layer. In an exemplary embodiment, the photoactive layer includes at least a single layer of the alloyed ternary nanocrystals. In an exemplary embodiment, at least a portion of the nanocrystals includes a material selected from the group consisting of metals and Group II-VI, Group III-V, and Group IV semiconductors and alloys thereof. In an exemplary embodiment, the nanocrystals include a lead chalcogenide or combinations thereof. In an exemplary embodiment, the nanocrystals include a PbSSe.

The present invention provides also provides a method of making ternary compound nanocrystals. In an exemplary embodiment, the method includes (1) degassing a solution of PbO, oleic acid and 1-octadecene (ODE) in a container, (2) heating the solution in the container, (3) injecting a first mixture of trioctylphosphine (TOP):Se solution, TMS2S, diphenylphosphine (DPP) and ODE into the heated solution, thereby forming a second mixture in the container, (4) adding ODE to the second mixture in the container, (5) growing the nanocrystals in the second mixture in a reaction in the container, and (6)_quenching the reaction, thereby resulting in precipitated nanocrystals in the container. In a further embodiment, the present invention further includes purifying the precipitated nanocrystals.

In an exemplary embodiment, the heating step includes heating the solution at approximately 150° C. In an exemplary embodiment, the heating includes heating the solution for approximately 1 hour.

In an exemplary embodiment, the growing includes growing the nanocrystals at approximately 150° C. In an exemplary embodiment, the growing includes growing the nanocrystals for approximately 90 seconds.

In an exemplary embodiment, the quenching includes (a) placing the container in a room-temperature water bath and (b) introducing anhydrous hexane into the container, thereby resulting in the precipitated nanocrystals.

In an exemplary embodiment, the purifying includes (a) twice precipitating the nanocrystals in hexane/ethanol and (b) precipitating the nanocrystals in hexane/acetone.

### BRIEF DESCRIPTION OF THE DRAWINGS

FIG. 1A illustrates a photovoltaic device in accordance with an exemplary embodiment of the present invention.

FIG. 1B illustrates a photovoltaic device in accordance with an exemplary embodiment of the present invention.

FIG. 2A is a flowchart in accordance with an exemplary embodiment of the present invention.

FIG. 2B is a flowchart in accordance with a further embodiment of the present invention.

FIG. 3A is a flowchart of the heating step in accordance with an exemplary embodiment of the present invention.

FIG. 3B is a flowchart of the heating step in accordance with an exemplary embodiment of the present invention.

FIG. 4A is a flowchart of the growing step in accordance with an exemplary embodiment of the present invention.

FIG. 4B is a flowchart of the growing step in accordance with an exemplary embodiment of the present invention.

FIG. 5 is a flowchart of the quenching step in accordance with an exemplary embodiment of the present invention.

FIG. 6 is a flowchart of the purifying step in accordance with an exemplary embodiment of the present invention.

FIG. 7A is a bright-field transmission electron microscopy (TEM) image of nanoparticles in accordance with an exemplary embodiment of the present invention.

FIG. 7B is an energy filtered TEM (EF-TEM) image of nanoparticles in accordance with an exemplary embodiment of the present invention.

FIG. 7C is an EFTEM image of nanoparticles in accordance with an exemplary embodiment of the present invention.

FIG. 7D is a TEM image of nanoparticles in accordance with an exemplary embodiment of the present invention.

FIG. 8 is a Rutherford back scattering data plot in accordance with the present invention.

FIG. 9A is an absorbance spectra plot in accordance with the present invention.

FIG. 9B is an absorbance and photoluminescence plot in accordance with the resent invention.

FIG. 10A is a current-voltage plot in accordance with the present invention.

FIG. 10B is an efficiency plot in accordance with the resent invention.

FIG. 11 is a TEM image of nanoparticles in accordance with an exemplary embodiment of the present invention.

FIG. 11 is a TEM image of nanoparticles in accordance with an exemplary embodiment of the present invention.

FIG. 12 is an X-Ray diffraction (XRD) spectrum of nanocrystals in accordance with an exemplary embodiment of the present invention.

FIG. 13 illustrates a nanocrystals in accordance with an exemplary embodiment of the present invention.

FIG. 14 is an absorbance plot in accordance with the present invention.

FIG. 15 is a Rutherford Backscattering Spectrometry (RBS) plot in accordance with the present invention.

### DETAILED DESCRIPTION OF THE INVENTION

The present invention provides a photovoltaic device. In an exemplary embodiment, the photovoltaic device includes a substrate having a thin film disposed thereon, where the thin film includes alloyed ternary nanocrystals. In an exemplary embodiment, the thin film includes a photoactive layer. In an exemplary embodiment, the photoactive layer includes at least a single layer of the alloyed ternary nanocrystals. In an exemplary embodiment, at least a portion of the nanocrystals includes a material selected from the group consisting of metals and Group II-VI, Group III-V, and Group IV semiconductors and alloys thereof. In an exemplary embodiment, the nanocrystals include a lead chalcogenide or combinations thereof. In an exemplary embodiment, the nanocrystals include a PbSSe.

The present invention provides also provides a method of making ternary compound nanocrystals. In an exemplary embodiment, the method includes (1) degassing a solution of PbO, oleic acid and 1-octadecene (ODE) in a container, (2) heating the solution in the container, (3) injecting a first mixture of trioctylphosphine (TOP):Se solution, TMS₂S, diphenylphosphine (DPP) and ODE into the heated solution, thereby forming a second mixture in the container, (4) adding ODE to the second mixture in the container, (5) growing the nanocrystals in the second mixture in a reaction in the container, and (6)_quenching the reaction, thereby resulting in precipitated nanocrystals in the container. In a further embodiment, the present invention further includes purifying the precipitated nanocrystals.

### Device

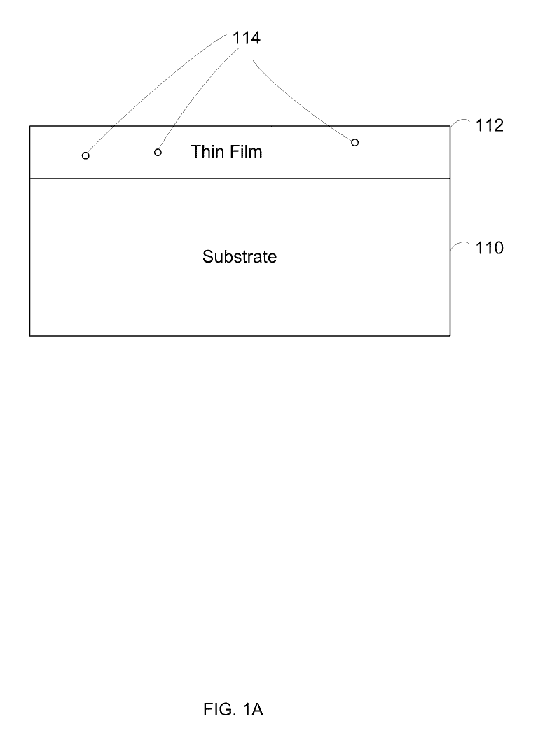

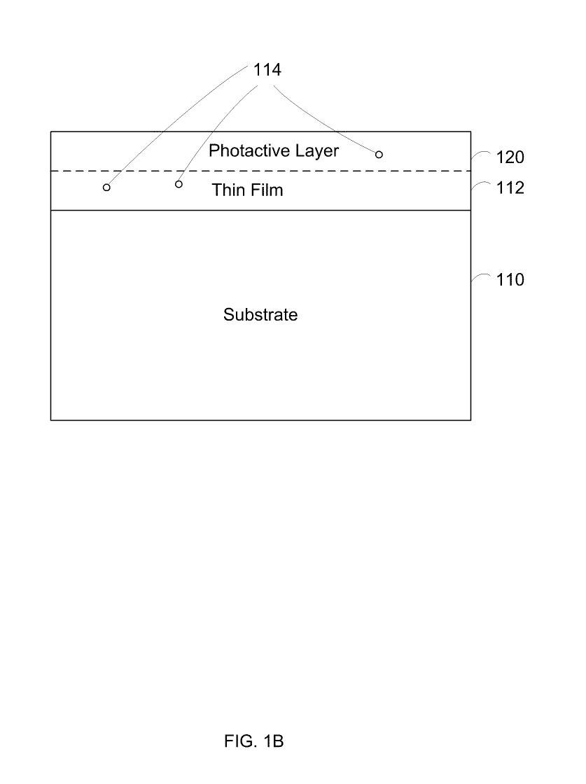

Referring to FIG. 1A, in an exemplary embodiment, the present invention includes a includes a substrate 110 having a thin film 112 disposed thereon, where thin film 112 includes alloyed ternary nanocrystals 114. Referring to FIG. 1B, in an exemplary embodiment, thin film 112 includes a photoactive layer 120. In an exemplary embodiment, photoactive layer 120 includes at least a single layer of alloyed ternary nanocrystals 114. In an exemplary embodiment, at least a portion of nanocrystals 114 includes a material selected from the group consisting of metals and Group II-VI, Group III-V, and Group IV semiconductors and alloys thereof. In an exemplary embodiment, nanocrystals 114 include a lead chalcogenide or combinations thereof. In an exemplary embodiment, nanocrystals 114 include a PbSSe.

### Method

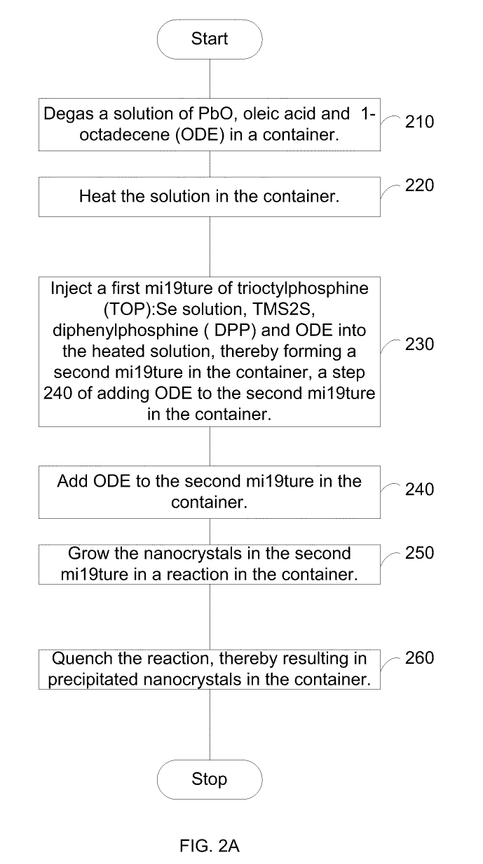

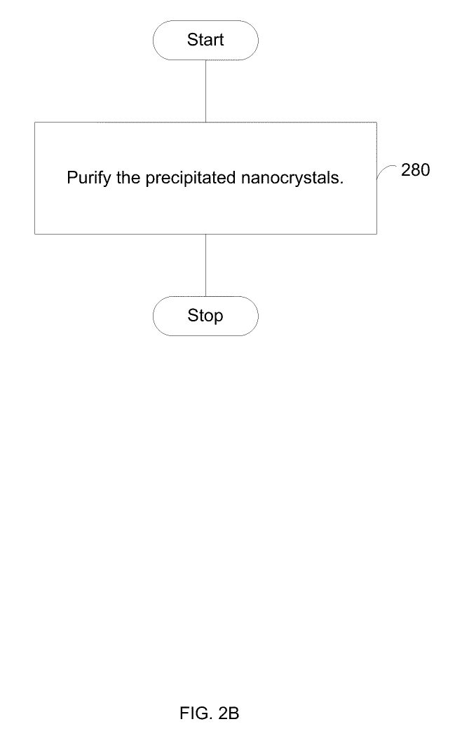

Referring to FIG. 2A, in an exemplary embodiment, the present invention includes a step 210 of degassing a solution of PbO, oleic acid and 1-octadecene (ODE) in a container, a step 220 of heating the solution in the container, a step 230 of injecting a first mixture of trioctylphosphine (TOP):Se solution, TMS₂S, diphenylphosphine (DPP) and ODE into the heated solution, thereby forming a second mixture in the container, a step 240 of adding ODE to the second mixture in the container, a step 250 of growing the nanocrystals in the second mixture in a reaction in the container, and a step 260 of quenching the reaction, thereby resulting in precipitated nanocrystals in the container. Referring to FIG. 2B, in a further embodiment, the present invention further includes a step 280 of purifying the precipitated nanocrystals.

Heating

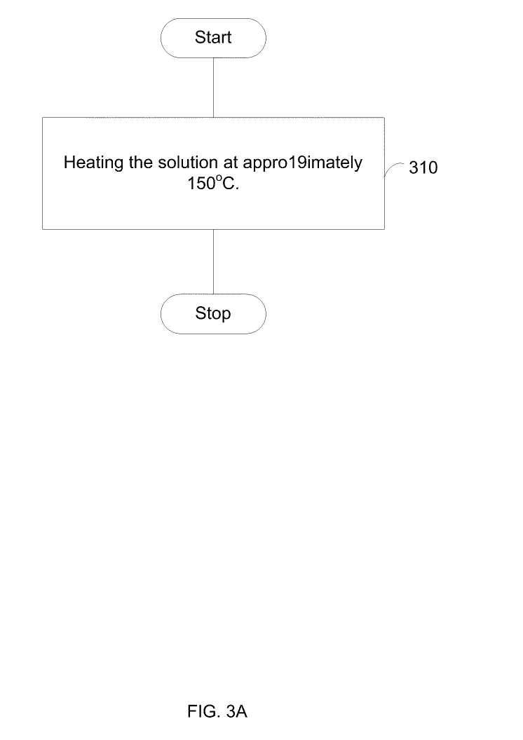

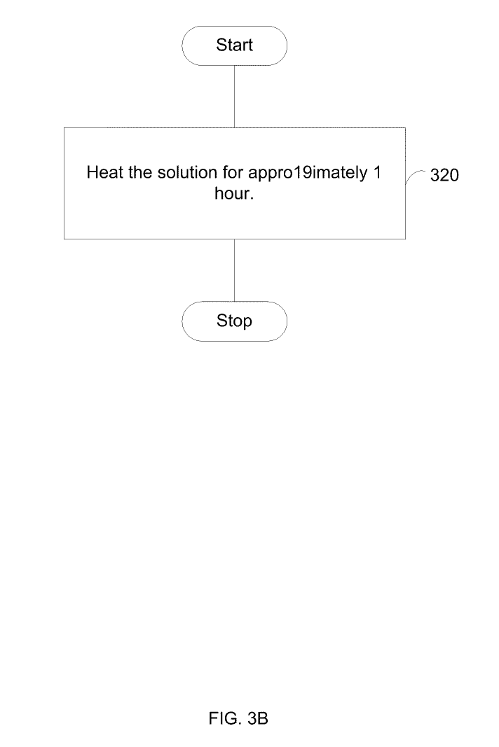

Referring to FIG. 3A, in an exemplary embodiment, heating step 210 includes a step 310 of heating the solution at approximately 150° C. Referring to FIG. 3B, in an exemplary embodiment, heating step 210 includes a step 320 of heating the solution for approximately 1 hour.

Growing

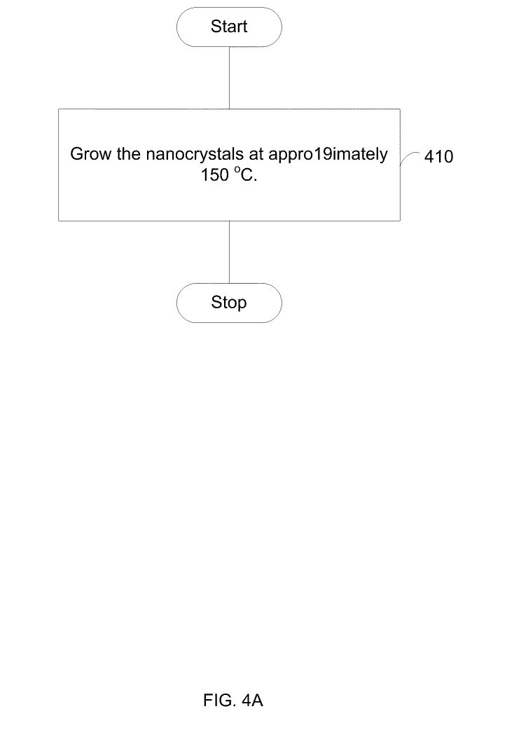

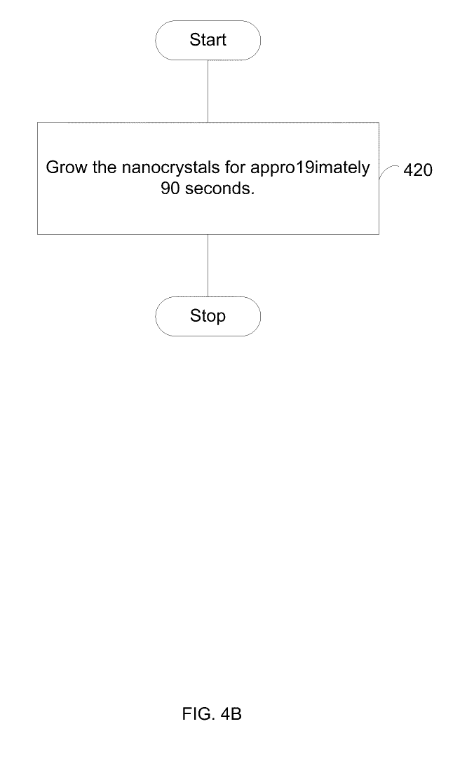

Referring to FIG. 4A, in an exemplary embodiment, growing step 250 includes a step 410 of growing the nanocrystals at approximately 150° C. Referring to FIG. 4B, in an exemplary embodiment, growing step 250 includes a step 420 of growing the nanocrystals for approximately 90 seconds.

Quenching

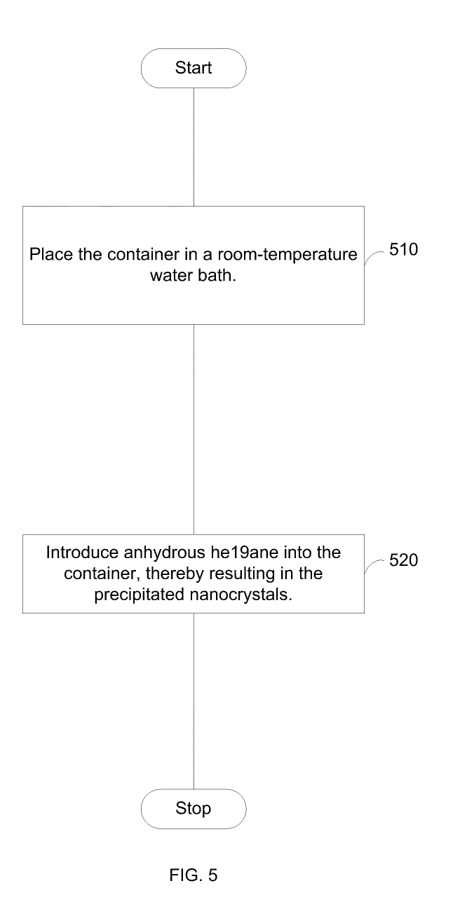

Referring to FIG. 5, in an exemplary embodiment, quenching step 260 includes a step 510 of placing the container in a room-temperature water bath and a step 520 of introducing anhydrous hexane into the container, thereby resulting in the precipitated nanocrystals.

Purifying

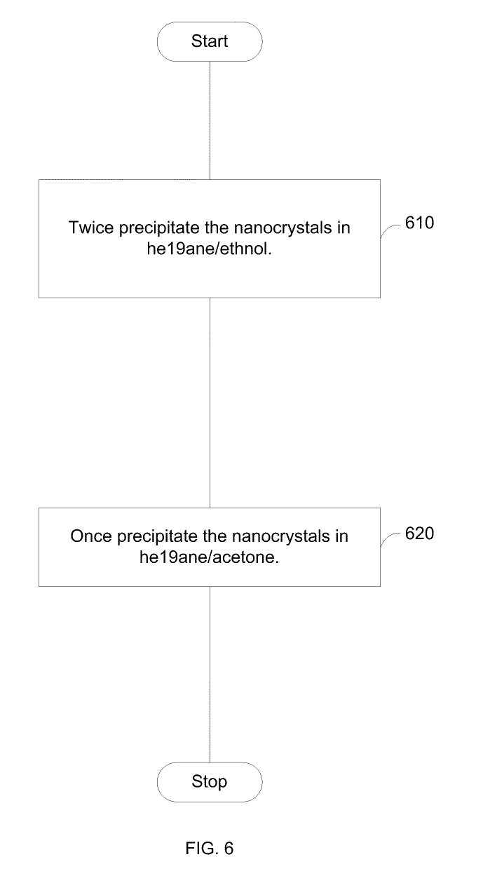

Referring to FIG. 6, in an exemplary embodiment, purifying step 280 includes a step 610 of twice precipitating the nanocrystals in hexane/ethanol and a step 620 of once precipitating the nanocrystals in hexane/acetone.

### General

The present invention provides a method of creating ternary PbSₓSe₁₋ₓ to simultaneously optimize both carrier transport and voltage. Although it remains a challenge to synthesize uniform ternary PbSₓSe₁₋ₓ nanocrystals^{13, 14} compared to the widely studied cadmium chalcogenides alloys,¹⁵⁻¹⁷, the present invention allows for obtaining monodisperse, highly crystalline nanocrystals using a one-pot, hot injection synthesis. It has been observed that the combination of better J_{SC} and V_{OC} are realized in photovoltaic (PV) devices containing ternary (e.g., PbSₓSe₁₋ₓ) nanocrystals produced by the present invention relative to pure phase PbS and PbSe nanocrystals. Se and S compositions are closely related to the photovoltaic parameters J_{SC} and V_{OC} respectively.

In some embodiments the present invention discloses the use of Group II-VI, Group III-V, Group IV semiconductor materials and metals for use in ternary compound nanoparticles. More preferred are combinations can include PbSSe, GaAs, CuInS₂, CuInSe₂, AlGaAs, InGaAs, or ternary compounds including Pb, S, Se, Cd, Ge and Si. A suitable “metal” refers to elements of the periodic table such as alkali metals, alkali earth metals, transition metals and post-transition metals. Alkali metals include Li, Na, K, Rb and Cs. Alkaline earth metals include Be, Mg, Ca, Sr and Ba. Transition metals include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg and Ac. Post-transition metals include Al, Ga, In, Tl, Ge, Sn, Pb, Sb, Bi, and Po. One of skill in the art will appreciate that the metals described above can each adopt several different oxidation states, all of which are useful in the present invention. In some instances, the most stable oxidation state is formed, but other oxidation states are useful in the present invention. Semiconductor material binary combinations to which a third compound can be added to improve performance can include CdSe, CdTe, InP, InAs, CdS, ZnS, ZnSe, ZnTe, HgTe, GaN, GaP, GaAs, GaSb, InSb, Si, Ge, AlAs, AlSb, PbSe, PbS, PbTe,

The present invention used alloying to tune the composition of and to achieve the ternary nanocrystal with optimum photovoltaic properties. Lead chalcogenides are the only materials thus far to make high efficiency non-sintered nanocrystal solar cells because of their large exciton Bohr radius. The present invention used alloying to obtain nanocrystals with desirable bandgap, transport, and surface passivation while maintaining the advantages of the binary compound counterparts. The present invention produced ternary nanocrystals with novel photovoltaic properties introduced by alloying as a result of quantum confinement effects and the residual nanoscale size of the components in the nanocrystal film.

The present invention creates highly confined nanocrystals of the ternary compound PbSxSe1-x. The present invention produces crystalline, monodisperse alloyed nanocrystals by using a one-pot, hot injection reaction. Photovoltaic devices made using ternary nanoparticles produced via the present invention are shown to be more efficient than either pure PbS or pure PbSe based nanocrystal devices.

Other methods for making nanoparticles for use in photovoltaic devices and for making photovoltaic devices using nanoparticles in layers or thin films are previously described such as in WO2003/081683, WO2008/127378, and WO2009/111388, which are hereby incorporated by reference for all purposes. By “nanocrystal” it is meant to include crystalline particles of all shapes, symmetries and sizes such as spherical, rods, tetrapods, etc. or branched or unbranched. Preferably, they have at least one dimension less than about 100 nanometers, but they are not so limited. Rods may be of any length. “Nanocrystal”, and “nanoparticle” can and are used interchangeably herein. In some embodiments of the invention, the nanocrystal particles may have two or more dimensions that are less than about 100 nanometers. The nanocrystals may be core/shell type or core type. For example, some branched nanocrystal particles according to some embodiments of the invention can have arms that have aspect ratios greater than about 1. In other embodiments, the arms can have aspect ratios greater than about 5, and in some cases, greater than about 10, etc. The widths of the arms may be less than about 200, 100, and even 50 nanometers in some embodiments. For instance, in an exemplary tetrapod with a core and four arms, the core can have a diameter from about 3 to about 4 nanometers, and each arm can have a length of from about 4 to about 50, 100, 200, 500, and even greater than about 1000 nanometers. Of course, the tetrapods and other nanocrystal particles described herein can have other suitable dimensions. In embodiments of the invention, the nanocrystal particles may be single crystalline or polycrystalline in nature.

### Example

The present invention produced ternary PbSₓSe₁₋ₓ nanocrystals. Lead oxide (PbO, 99.999%), selenium (99.99%), oleic acid (OA, tech. grade, 90%), diphenylphosphine (DPP, 98%), 1,3-benzenedithiol (BDT, >98%), bis(trimethylsilyl) sulfide (TMS₂S, purum), 1-octadecene (ODE, 90%), anhydrous solvents and aluminum shot (99.999%) were purchased from Sigma-Aldrich Co. and used as received. Trioctylphosphine (TOP, >97%) was acquired from Strem Chemicals, Inc. Nanocrystal synthesis was performed under argon atmosphere using standard air-free Schlenk line techniques.

The synthesis scheme of the present invention involves several steps. First, a solution of 446 mg PbO (2 mmol), 1.4 g oleic acid (5 mmol), and 10 g ODE was degassed and heated to 150° C. in a 50 mL three-neck flask for one hour. Next, a mixture of proper amount 1M TOP:Se solution, TMS₂S, DPP (40 mg) and ODE was then rapidly injected into this hot solution. The Se and S precursor ratio was tuned to specific values, but the total amount was kept at 1 mmol. ODE was added to dilute the precursor solution to 2 ml total. Then, the nanocrystals were grown at 150° C. for 90 s, and the reaction was rapidly quenched by placing the flask in a room-temperature water bath and injecting 5 mL of anhydrous hexane. Finally, the nanocrystals were purified by precipitation twice in hexane/ethanol and once in hexane/acetone and stored in a glovebox.

### Results

Achieving and characterizing a uniformly alloyed nanocrystal remains difficult.¹⁶ Complications arise from the difference in precursor solubility and reactivity at a given temperature, and in the difference between nucleation and growth of nanocrystals.

Since TMS₂S is more reactive than TOP:Se, the stoichiometric ratio of S to Se in the resulting nanocrystal sample was greater than the injected precursor ratio. The composition of the resulting nanocrystals was characterized using energy filtered transmission electron microscopy (EF-TEM)¹⁸ to determine whether the nanocrystals resulted in separately nucleated PbS and PbSe, core-shell architectures, or alloyed composites.

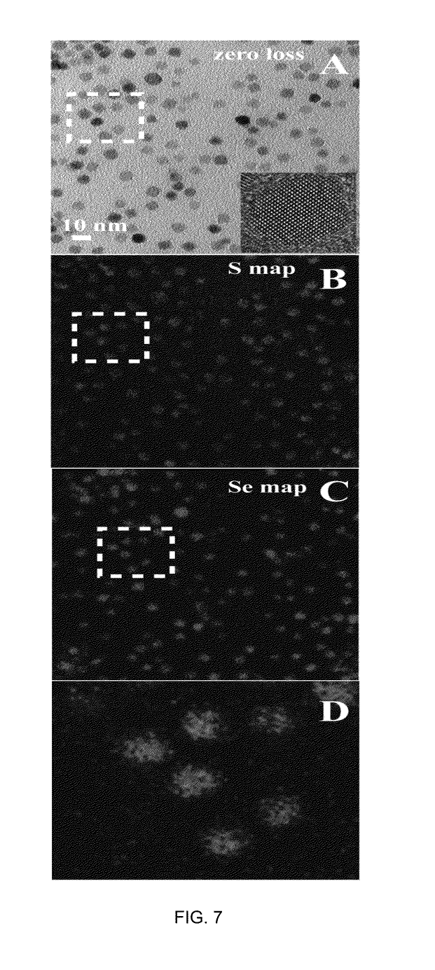

FIG. 7A, FIG. 7B, and FIG. 7C show zero loss and EF-TEM images of a sample of ˜7 nm PbS_{0.7}Se_{0.3} taken at the same position on a TEM grid. To achieve strong elemental signals, for EF-TEM we found it necessary to use larger nanocrystals and exchange the oleate ligands on the nanocrystal surface by adding a small amount of butylamine and washing the nanocrystals the following day. All nanocrystals in FIG. 7A (zero loss) appear in both the S mapping of FIG. 1B, and at a corresponding location in the Se mapping of FIG. 1C. The selected areas in FIG. 7A, FIG. 7B, and FIG. 7C make the comparison easier and are shown in greater detail in FIG. 7D with the S and Se maps overlaid. The TEM results indicate that, to some extent, both Se and S are distributed inside each nanocrystal without apparent phase separation. Note that S is more prevalent than Se in the sample (i.e. PbS_{0.7}Se_{0.3}). FIG. 7A inset shows a high-resolution TEM image of a single nanocrystal. Uniform lattice structure with no obvious stack faults or core-shell structure is observed. See Supporting Information for additional TEM images of well-packed oleate-capped ternary PbSSe nanocrystals. FIG. 7A is a bright-field TEM image showing 7 nm PbS_{0.7}Se_{0.3} nanocrystals. The scale bar in FIG. 7A represents 10 nm. The inset in FIG. 7A Inset shows the high degree of crystallinity of a single ternary nanocrystal without obvious core-shell configuration. FIG. 7B is an energy filtered TEM (EF-TEM) image at the same location as in FIG. 7A, showing regions containing sulfur. FIG. 7C is an EF-TEM image showing a selenium map. FIG. 7D depicts the insets in FIG. 7A, FIG. 7B, and FIG. 7C enlarged and overlaid to show sulfur and selenium in each nanocrystal.

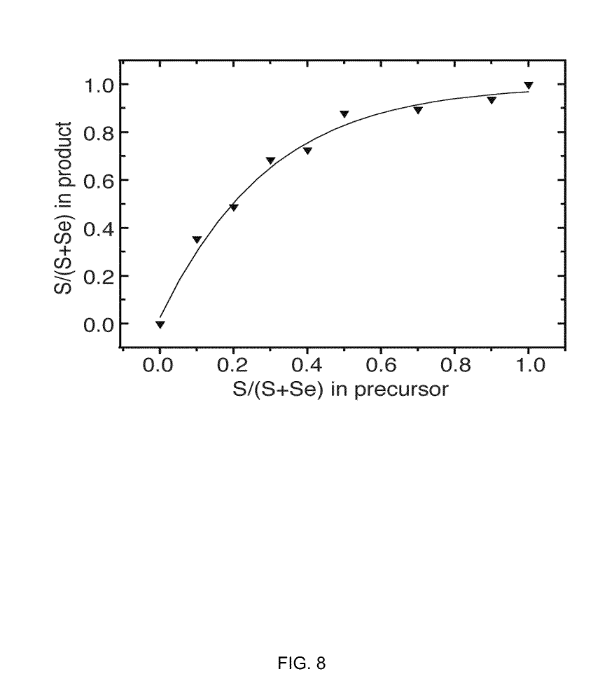

Rutherford backscattering spectroscopy (RBS) was then used to investigate the actual anion ratio. FIG. 8 shows RBS data for a series of samples where the relative amount of S in the precursor ratio (S/(S+Se)) was systematically varied from 0 to 1. The graph shows a clear nonlinearity in the percent incorporation of anions in the nanocrystals compared to fraction present in the original precursor solution. For example: only 30% S in the precursor is needed to make nanocrystals with 70% S composition. Presumably, this nonlinearity results from the different reactivity of the chalcogen precursors. We also find that for longer reaction times, more Se is incorporated (see FIG. S5 in Supporting Information) indicating a possible radial gradient in composition; however, to be consistent, all nanocrystals used in devices were only allowed to grow for 90 seconds, thus suppressing such a gradient. RBS data shows that all samples display Pb rich composition regardless of whether or not Pb was in excess during synthesis. FIG. 8 depicts Rutherford back scattering data showing the relative amount of sulfur in the product versus the relative amount of sulfur in the precursor injection solution. The bowing is due to the higher reactivity of the sulfur precursor (TMS₂S) to that of the selenium precursor (TOP:Se).

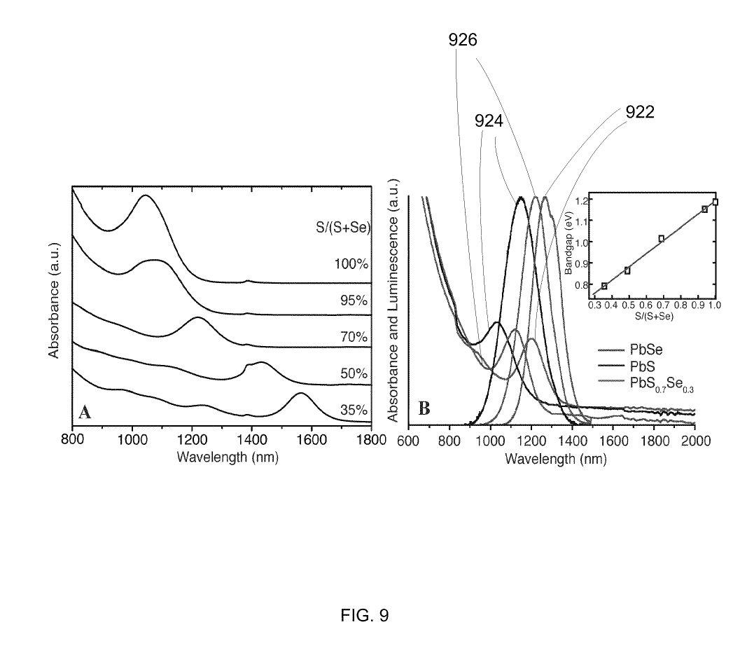

For optical characterization, the alloyed PbSSe nanocrystals were suspended in tetrachloroethylene. Absorbance spectra for nanocrystals with different compositions are displayed in FIG. 9A. Arising from the smaller bandgap of PbSe relative to PbS for a given size,¹⁹ we notice the red shift of the first excitation peak with reduced S composition. This trend can be observed more clearly in the inset of FIG. 9B which shows a linear relationship between the nanocrystal bandgap energy and the composition ratios. Vegard's Law predicts the structure and function of many alloyed materials: E_{alloy}=χE_{A}+(1−χ)E_{B}, where χ is the mole fraction, E_{A}, E_{B}, and E_{alloy} are the band gap energy (or other properties) of pure composition A, pure composition B, and the alloyed material, respectively. However, this linear relationship does not apply to several classes of semiconductor alloys. For example, both bulk and nanocrystal CdSeₓTe₁₋ₓ alloys display pronounced nonlinear “optical bowing” effects.^{16, 17} Zunger and coworkers explain this type of observation by identifying three structural and electronic factors leading to nonlinearity of ternary compounds: different atomic size, electronegativity values of ions, and different lattice constants of the binary structures.^{20, 21} A substantial lattice mismatch (11%) also exists between the binary semiconductors CdS and CdTe which leads to enhanced nonlinear effects there also. However, in the case of PbSₓSe₁₋ₓ, there is only a 2% lattice mismatch between PbS and PbSe, so it is reasonable to observe less nonlinearity with composition in this alloy system, considering also that the difference in atomic size and electronegativity are the same as that for the cadmium chalcogenides.

FIG. 9A depicts absorbance spectra of alloyed nanocrystals with gradually increased S concentration. All nanocrystals are ˜4 nm in diameter and are grown for 90 sec. FIG. 9B shows absorbance and photoluminescence of pure PbSe (plots 922), pure PbS (plots 924), and PbS_{0.7}Se_{0.3} (plots 926) with similar size. The PL shows no broadening over the pure binary nanocrystals. The inset in FIG. 9B shows the variation of nanocrystals bandgap energy with different S concentrations.

The absorbance and photoluminescence (PL) of PbS, PbSe, and PbS_{0.7}Se_{0.3} nanocrystals with similar diameter are shown in FIG. 9B. The full width at half maximum (FWHM) of PL is 188 meV, 136 meV, 122 meV for PbS, PbS_{0.7}Se_{0.3} and PbSe respectively. The structured absorbance and relatively narrow PL peaks of alloyed nanocrystal indicate the sample is nearly monodisperse, which exclude the possibility of the co-existence of separate PbSe and PbS in the final synthesized nanocrystals. The uniformity of our alloyed nanocrystal structure can be further indicated by the 100 nm Stokes shift, which lies between 120 nm for PbS and 70 nm for PbSe. This result is also consistent with Vegard's Law for a true alloy.

In some embodiments, the present invention provides a photovoltaic device comprising a cathode; an anode; and a photoactive layer comprising a monolayer of the ternary nanocrystal particle, wherein the photoactive layer is disposed between the cathode and the anode.

We fabricated Schottky junction back contact devices containing ternary Pb chalcogenide nanocrystals using methods reported by Nozik and coworkers for binary PbX nanocrystals.^{6, 22} Briefly, patterned ITO coated glass slides were acquired from Thin Film Devices Inc (20±5 ohms/sq, ITO thickness ˜300 nm). The substrates were cleaned by ultrasonication in various solvents and films of nanocrystals were deposited by sequentially dipping the substrate in a hexane solution containing the nanocrystals (˜25 mg/ml) followed by dipping in a 0.01M BDT solution in acetonitrile.²³ This process was repeated such that the resulting film thickness was near 100 nm as was shown to be the optimum for PbSe devices.²⁴ In order to verify reproducibility of the data, three devices were made for each batch of nanocrystal with eight working pixels on each device (active area of 4 mm²). AM1.5G illumination was obtained with a Spectra Physics Oriel 300 W Solar Simulator. The integrated intensity was set to 100 mW/cm² using a thermopile radiant power meter (Spectra Physics Oriel, model 70260) with fused silica window, and verified with a Hamamatsu S1787-04 diode.

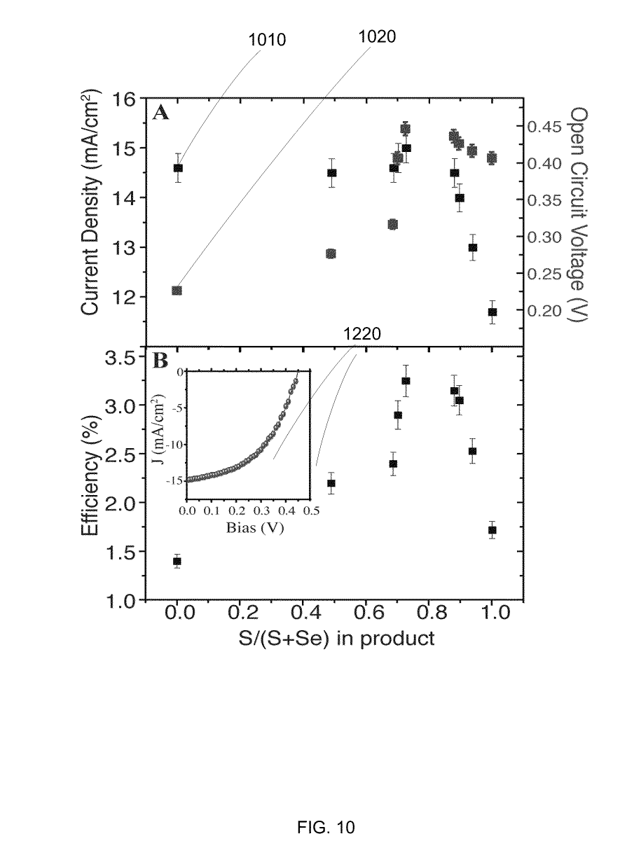

FIG. 10A and FIG. 10B show the composition-dependent device performance. The x-axis represents composition change from pure PbSe, to pure PbS, versus various photovoltaic device parameters. Previous reports of PbS and PbSe nanocrystal devices have revealed higher V_{OC} for PbS devices but larger J_{SC} with PbSe.^{6, 23, 25} Our binary PbS and PbSe results agree, but interestingly, are better in ternary PbSₓSe₁₋ₓ nanocrystals. The J_{SC} is mostly unaffected between S concentrations of 0 to 65%. Beyond 65% the J_{SC} rises slightly and then begins dropping at 80%. The V_{OC} is as much as double that of PbSe when using PbS_{0.7}Se_{0.3}.

As a result of both improved J_{SC} and V_{OC}, ternary PbSₓSe₁₋ₓ nanocrystals achieve better efficiency than pure binary nanocrystal PbSe and PbS, as shown in FIG. 10B. In fact, all devices employing ternary nanocrystals regardless of the actual anion ratio performed better than each binary control device. PbS_{0.7}Se_{0.3} has the best 1-Sun power conversion efficiency of 3.3%, with a J_{SC} of 14.8 mA/cm², a V_{OC} of 0.45 V and a fill factor of 50%. The J-V curve is shown in the inset of FIG. 10B. The efficiency of devices based on pure PbS and PbSe is 1.7% and 1.4% respectively, which is consistent with previously reported results.^{6, 25} In our devices, there is a two-fold improvement for optimized alloyed nanocrystals compared to binary nanocrystals.

FIG. 10A illustrates short circuit current density (plot 1010) and open circuit voltage (plot 1020) of solar cells made of nanocrystals with different varying S concentrations. FIG. 10B illustrates 1-sun efficiency of devices made of nanocrystals with different S concentrations. J-V curve of best performing solar cell device based on PbS_{0.7}Se_{0.3} nanocrystals is shown in the inset of part (B). The error bars indicate the variance among 8 devices on each substrate.

It has been documented that PbS and PbSe arrays of this nature have charge trapping states within the bandgap arising from ligand exchange and potentially damage during the metal deposition.^{22, 26, 27} We hypothesize that the better performance of ternary nanocrystals is due to a combination of material properties as well as a redistribution of the trap states. The higher current produced by PbSₓSe₁₋ₓ, may arise from a significantly larger exciton Bohr radius than PbS (but smaller than PbSe) due to the incorporation of Se (46 nm for PbSe and 18 nm for PbS). The larger Bohr radius delocalizes the carriers, establishing greater electronic coupling between nanocrystals, which can diminish the effects of nanocrystal surface traps and therefore facilitate charge transport. As indicated in FIG. 10A, an incorporation of ˜30% Se into PbS substantially improves the current density of the cell.

PbS cells have a larger V_{OC} compared to PbSe with the same bandgap. According to Schottky junction theory, the barrier height (proportional to V_{OC}) of an ideal metal-semiconductor contact is determined by the relative position between metal work function and semiconductor Fermi energy.²⁸ In all devices reported here, Aluminum (work function of 4.28 eV)²⁹ is used as the contact and the p-type nanocrystal films have a Fermi level deeper than Aluminum. The size dependent conduction and valence band edge of PbS and PbSe nanocrystals have recently been measured and PbS is reported to have energy levels closer to vacuum energy than PbSe.¹⁹ However, in practical Schottky junctions, one major limitation is that the V_{OC} cannot exceed half the bandgap. Otherwise, the minority carrier density would be larger than the majority carrier density at the junction, thus forming an inversion layer.³⁰ In the situation of these devices, therefore, the true limit of the V_{OC} is governed by the difference between the intrinsic level (at mid gap) and the Fermi level of the nanocrystal film, so long as the work function of the metal contact is closer in energy to vacuum than the intrinsic energy of the semiconductor. Since the Fermi level of nanocrystals is closely related to the trap states, the density of trap states within the bandgap is most likely the cause of the differing voltages of the materials. Due to different surface energies of the binary phases to the ternary, the position and density of traps states at least at the surface in PbS, PbSe, and PbSₓSe₁₋ₓ may vary. This difference could determine the relative position of the Fermi level to the valence band edge of the nanocrystal film and therefore may lead to different open circuit voltages.

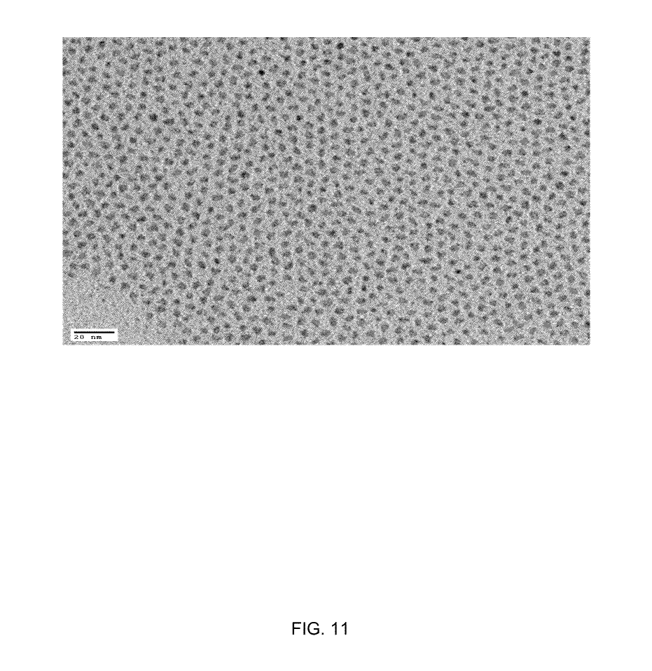

FIG. 11 is a TEM image of typical nanocrystals produced by the present invention employed in the high efficiency devices. S/(S+Se)=70%.

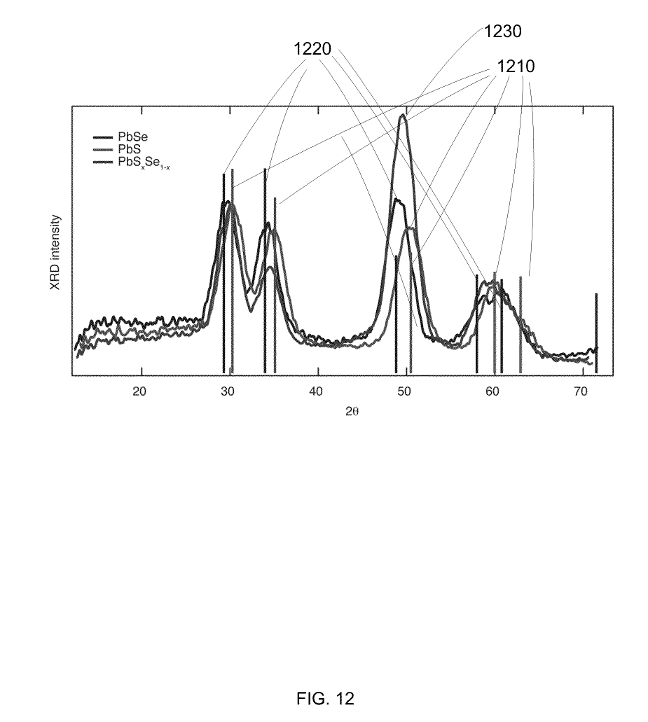

FIG. 12 is an X-Ray Diffraction spectrum of nanocrystals of PbS (plot 1210), PbSe (plot 1220) and PbSₓSe₁₋ₓ (plot 1230). There is little shift between the peaks of PbS and PbSe. However the ternary nanocrystals peaks fall between the values of the binary nanocrystals.

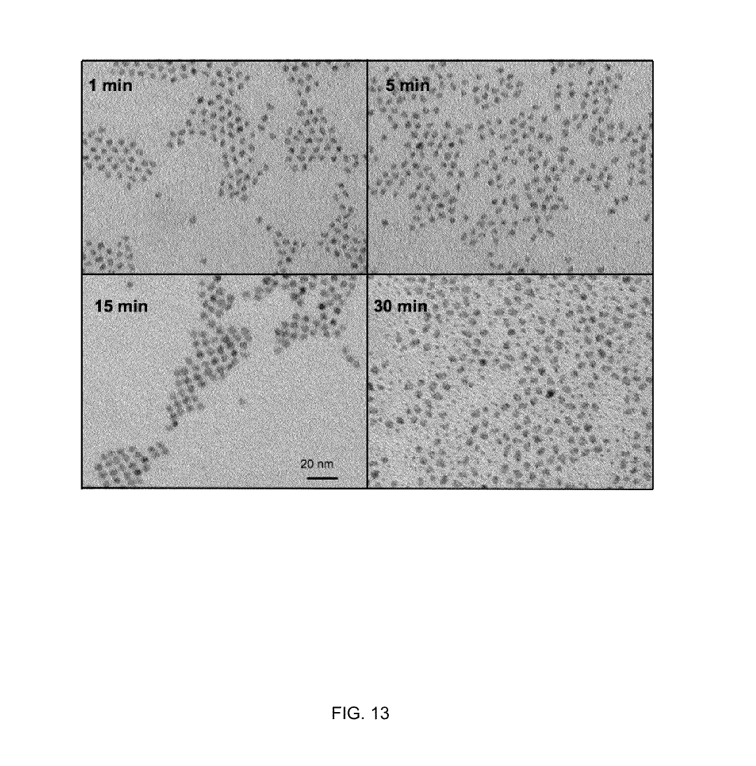

FIG. 13 depicts a synthesis for PbSSe nanocrystals performed with timed aliquot removal to demonstrate the nanocrystal growth evolution. The best sample dispersity is seen in fast reactions. The scale bar is 20 nm for all images in FIG. 13.

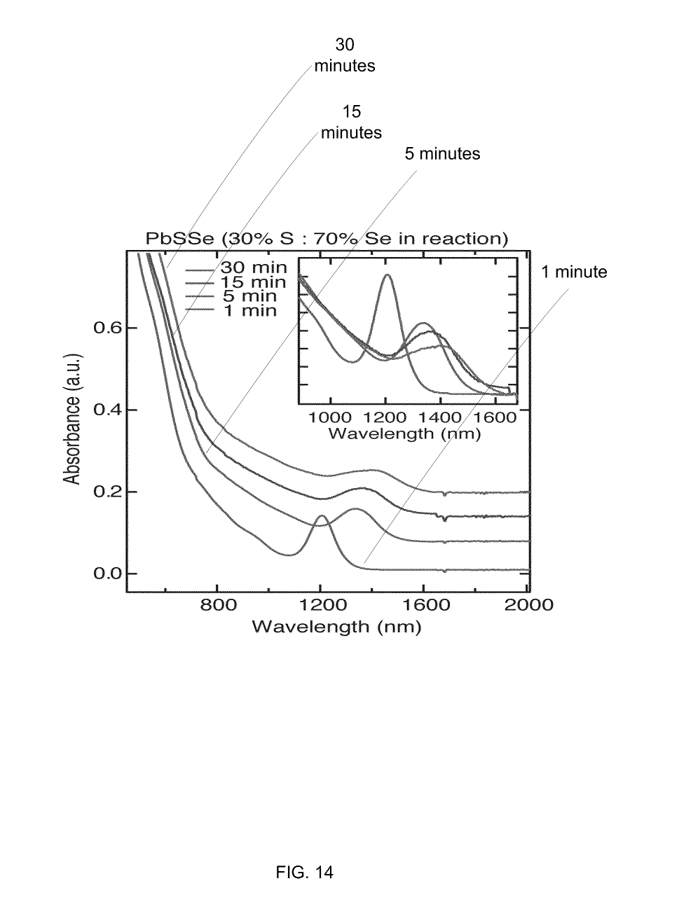

FIG. 14 illustrates absorbance of nanocrystals during the timed growth, offset for clarity, in accordance with the present invention. Subsequent growth times resulted in a broadened first exciton as well as a decrease in the bandgap. Since sharpest peaks are observed at short growth time, a reaction time of 90 seconds was used for all device work in the manuscript. Based on the width of the first exciton peak we estimate the dispersion in sample size to increase from below 10% to slightly greater than 20% after 30 mins.

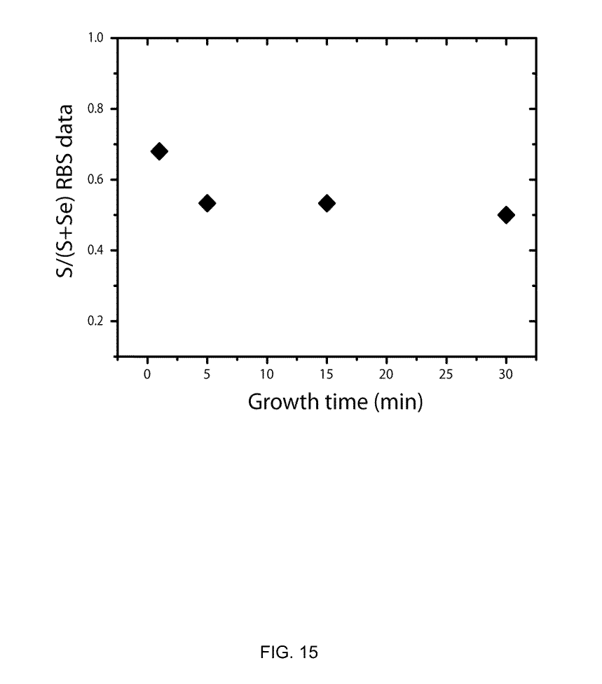

FIG. 15 depicts RBS data for the S composition of nanocrystals taken from aliquots removed at varying time after the anion precursor injection.

The above examples are provided to illustrate the invention but not to limit its scope. Other variants of the invention will be readily apparent to one of ordinary skill in the art and are encompassed by the appended claims. All publications, databases, and patents cited herein are hereby incorporated by reference for all purposes

### REFERENCES

The following additional documents are hereby incorporated by reference:
1. Manna, L., Scher, E. C., Alivisatos, A. P. Journal of the American Chemical Society 2000, 122, (51), 12700-12706;
2. Milliron, D. J., Hughes, S. M., Cui, Y., Manna, L., Li, J. B., Wang, L. W., Alivisatos, A. P. Nature 2004, 430, (6996), 190-195;
3. Talapin, D. V., Yu, H., Shevchenko, E. V., Lobo, A., Murray, C. B. Journal of Physical Chemistry C 2007, 111, (38), 14049-14054;
4. Whaley, S. R., English, D. S., Hu, E. L., Barbara, P. F., Belcher, A. M. Nature 2000, 405, (6787), 665-668;
5. Huynh, W. U., Dittmer, J. J., Alivisatos, A. P., Science 2002, 295, (5564), 2425-2427;
6. Luther, J. M., Law, M., Beard, M. C., Song, Q., Reese, M. O., Ellingson, R. J., Nozik, A. J., Nano Letters 2008, 8, (10), 3488-3492;
7. Gur, I., Fromer, N. A., Geier, M. L., Alivisatos, A. P., Science 2005, 310, (5747), 462-465;
8. Robel, I., Subramanian, V., Kuno, M., Kamat, P. V., Journal of the American Chemical Society 2006, 128, (7), 2385-2393;
9. Gur, I., Fromer, N. A., Alivisatos, A. P., Journal of Physical Chemistry B 2006, 110, (50), 25543-25546;
10. Wu, Y., Wadia, C., Ma, W. L., Sadtler, B., Alivisatos, A. P., Nano Letters 2008, 8, (8), 2551-2555;
11. Yu, P. R., Zhu, K., Norman, A. G., Ferrere, S., Frank, A. J., Nozik, A. J., Journal of Physical Chemistry B 2006, 110, (50), 25451-25454;
12. Zaban, A., Micic, O. I., Gregg, B. A., Nozik, A. J., Langmuir 1998, 14, (12), 3153-3156;
13. Brumer, M., Kigel, A., Amirav, L., Sashchiuk, A., Solomesch, O., Tessler, N., Lifshitz, E., Advanced Functional Materials 2005, 15, (7), 1111-1116;
14. Kigel, A.; Brumer, M.; Sashchiuk, A.; Amirav, L.; Lifshitz, E.; Materials Science & Engineering C-Biomimetic and Supramolecular Systems 2005, 604-608;
15. Gurusinghe, N. P., Hewa-Kasakarage, N. N., Zamkov, M., Journal of Physical Chemistry C 2008, 112, (33), 12795-12800;
16. Swafford, L. A., Weigand, L. A., Bowers, M. J., McBride, J. R., Rapaport, J. L., Watt, T. L., Dixit, S. K., Feldman, L. C., Rosenthal, S. J., Journal of the American Chemical Society 2006, 128, (37), 12299-12306;
17. Bailey, R. E., Nie, S. M., Journal of the American Chemical Society 2003, 125, (23), 7100-7106;
18. Transmission electron microscopy analysis were performed using a FEI monochromated F20 UT Tecnai TEM equipped with a field emission gun, an energy loss spectrometer and a Gatan Image Filter (GIF). It was operated at 200 keV. The EFTEM images were obtained by using the three-window method;
19. Hyun, B.-R., Zhong, Y.-W., Bartnik, A. C., Sun, L., Abruna, H. D., Wise, F. W., Goodreau, J. D., Matthews, J. R., Leslie, T. M., Borrelli, N. F., ACS Nano 2008, 2, (11), 2206-2212;
20. Wei, S. H., Zhang, S. B., Zunger, A., Journal of Applied Physics 2000, 87, (3), 1304-1311;
21. Bernard, J. E., Zunger, A., Physical Review B 1987, 36, (6), 3199-3228;
22. Luther, J. M., Law, M., Song, Q., Perkins, C. L., Beard, M. C., Nozik, A. J., ACS Nano 2008, 2, (2), 271-280;
23. Koleilat, G. I., Levina, L., Shukla, H., Myrskog, S. H., Hinds, S., Pattantyus-Abraham, A. G., Sargent, E. H., ACS Nano 2008, 2, (5), 833-840;
24. Law, M., Beard, M. C., Choi, S., Luther, J. M., Hanna, M. C., Nozik, A. J., Nano Letters 2008, 8, (11), 3904-3910;
25. Johnston, K. W., Pattantyus-Abraham, A. G., Clifford, J. P., Myrskog, S. H., MacNeil, D. D., Levina, L., Sargent, E. H., Applied Physics Letters 2008, 92, (15);
26. Barkhouse, D. A. R., Pattantyus-Abraham, A. G., Levina, L., Sargent, E. H., ACS Nano 2008, 2, (11), 2356-2362;
27. Konstantatos, G., Levina, L., Fischer, A., Sargent, E. H., Nano Letters 2008, 8, (5), 1446-1450;
28. Sze, S. M., Physics of Semiconductor Devices. 2nd ed., John Wiley & Sons: New York, 1981;
29. Reese, M. O., White, M. S., Rumbles, G., Ginley, D. S., Shaheen, S. E., Applied Physics Letters 2008, 92, (5); and
30. Nelson, J., The Physics of Solar Cells, Imperial College Press: London, 2003.

### CONCLUSION

It is to be understood that the above description and examples are intended to be illustrative and not restrictive. Many embodiments will be apparent to those of skill in the art upon reading the above description and examples. The scope of the invention should, therefore, be determined not with reference to the above description and examples, but should instead be determined with reference to the appended claims, along with the full scope of equivalents to which such claims are entitled. The disclosures of all articles and references, including patent applications and publications, are incorporated herein by reference for all purposes.

What is claimed is:

1. A photovoltaic device comprising:
a substrate having a thin film disposed thereon, wherein the thin film comprises alloyed ternary nanocrystals.

2. The device of claim 1 wherein the thin film comprises a photoactive layer.

3. The device of claim 2 wherein the photoactive layer comprises at least a single layer of the alloyed ternary nanocrystals.

4. The device of claim 1 wherein at least a portion of the nanocrystals comprises a material selected from the group consisting of metals and Group II-VI, Group III-V, and Group IV semiconductors and alloys thereof.

5. The device of claim 1 wherein the nanocrystals comprise a lead chalcogenide or combinations thereof.

6. The device of claim 1 wherein the nanocrystals comprise PbSSe.

7. A method of making ternary compound nanocrystals, the method comprising:
degassing a solution of PbO, oleic acid and 1-octadecene (ODE) in a container;
heating the solution in the container;
injecting a first mixture of trioctylphosphine (TOP):Se solution, TMS₂S, diphenylphosphine (DPP) and ODE into the heated solution, thereby forming a second mixture in the container;
adding ODE to the second mixture in the container;
growing the nanocrystals in the second mixture in a reaction in the container; and
quenching the reaction, thereby resulting in precipitated nanocrystals in the container.

8. The method of claim 7 wherein heating comprises heating the solution at approximately 150° C.

9. The method of claim 8 wherein the heating comprises heating the solution for approximately 1 hour.

10. The method of claim 7 wherein the growing comprises growing the nanocrystals at approximately 150° C.

11. The method of claim 10 wherein the growing comprises growing the nanocrystals for approximately 90 seconds.

12. The method of claim 7 wherein the quenching comprises:
placing the container in a room-temperature water bath; and
introducing anhydrous hexane into the container, thereby resulting in the precipitated nanocrystals.

13. The method of claim 7 further comprising purifying the precipitated nanocrystals.

14. The method of claim 13 wherein the purifying comprises:
twice precipitating the nanocrystals in hexane/ethanol; and
once precipitating the nanocrystals in hexane/acetone.
